(19) United States
(12) Patent Application Publication
(10) Pub. No.: US 2016/0195432 A1
(43) Pub. Date: Jul. 7, 2016

(54) OPTICAL TRANSCEIVER MODULE

(71) Applicant: ELECTRONICS AND TELECOMMUNICATIONS RESEARCH INSTITUTE, Daejeon (KR)

(72) Inventor: Jiho JOO, Daejeon (KR)

(21) Appl. No.: 15/072,100

(22) Filed: Mar. 16, 2016

Related U.S. Application Data
(63) Continuation-in-part of application No. 14/180,917, filed on Feb. 14, 2014.

(30) Foreign Application Priority Data
Feb. 27, 2013 (KR) 10-2013-0021452

(51) Int. Cl. G01J 1/44; H05K 1/11; H05K 1/18

(52) U.S. Cl. CPC G01J 1/44; H05K 1/181; H05K 1/115; H05K 2201/10121; G01J 2001/444

(57) ABSTRACT

Provided is a optical transceiver module. The optical transceiver module includes a printed circuit board (PCB) configured to include a plurality of dielectric layers and a plurality of metal layers stacked alternately, a photodetector disposed on the PCB to convert an optical signal into an electrical signal, a compensator disposed on one side on the PCB and including a first transmission line that delivers an electrical signal, a power supply line configured to supply power to the photodetector, and a first high frequency connector configured to connect to the first transmission line to deliver the electrical signal, wherein the PCB includes a plurality of vias that electrically connect the plurality of dielectric layers and the plurality of metal layers, and the compensator protrudes from the PCB to compensate for a height difference from the photodetector.

### CROSS-REFERENCE TO RELATED APPLICATIONS

This U.S. non-provisional patent application is a continuation-in-part of U.S. application Ser. No. 14/180,917 filed Feb. 14, 2014, which claims priority under 35 U.S.C. §119 to Korean Patent Application No. 10-2013-0021452, filed on Feb. 27, 2013, the entire contents of which are hereby incorporated by reference.

### BACKGROUND OF THE INVENTION

The present disclosure herein relates to an optical transceiver module, and more particularly, to an optical transceiver module that uses a ceramic substrate or printed circuit board (PCB).

In general, a high-speed photoreceiver module includes an optical system collecting light, a photodetector, an external power supply line, and a high frequency connector. Also, a preamplifier may be used so as to amplify a high frequency signal photoelectrically transformed by a photodetector. Furthermore, the high-speed photoreceiver module may further include a noise reduction circuit for removing noise caused from external power and a function circuit for performing an additional function. Since a signal delivered between a photodetector and a preamplifier and between a preamplifier and a high frequency transmission line is a high-speed signal of more than about 10 Gb/s, the high frequency transmission line and its peripheral part may need to be designed precisely in consideration of parasite components affecting such a high-speed transmission property.

It is recommended that a noise reduction circuit reducing low frequency noise of DC power be attached to a power input unit of a photodetector and a preamplifier. The reason is that a high-performance high-speed preamplifier used in a high-speed photoreceiver module is sensitive electromagnetically. The noise reduction circuit includes a combination of a resistor, a capacitor, and an inductor. As such a noise reduction circuit is disposed and is connected to a power input unit, an additional printed circuit board is manufactured. Therefore, an internal structure of a photoreceiver module becomes complex and additional costs arise.

A connection between an individual part and a printed circuit board uses a bondwire. Typically, as the length of a bondwire becomes shorter, high-speed transmission characteristic becomes better. In order to reduce the usage length of a bondwire, an additional supporting part is configured to adjust a height difference between a photodetector, a preamplifier, a noise reduction circuit, a high frequency transmission line, and a high frequency connector. However, when a height difference between a plurality of components is adjusted by using an additional supporting part, manufacturing processes become complex and there are limitations in reducing the usage length of a bondwire. Therefore, if a stepped hole is formed by using a ceramic substrate manufactured with a stacked layer structure and a plurality of components are mounted on the ceramic substrate, manufacturing processes become simple and the usage length of a bondwire is reduced effectively.

### SUMMARY OF THE INVENTION

The present disclosure provides an optical transceiver module that has high transmission efficiency. The present disclosure also provides an optical transceiver module that has high production yield and has a simple manufacturing process.

An embodiment of the inventive concept provides an optical transceiver module includes a printed circuit board (PCB) configured to include a plurality of dielectric layers and a plurality of metal layers stacked alternately, a photodetector disposed on the PCB to convert an optical signal into an electrical signal, a compensator disposed on one side on the PCB and including a first transmission line that delivers an electrical signal, a power supply line configured to supply power to the photodetector, and a first high frequency connector configured to connect to the first transmission line to deliver the electrical signal, wherein the PCB includes a plurality of vias that electrically connect the plurality of dielectric layers and the plurality of metal layers, and the compensator protrudes from the PCB to compensate for a height difference from the photodetector.

In an embodiment, the first transmission line of the compensator and the photodetector may have a same height.

In an embodiment, the compensator may include any one of FR4, duroid, taconic or ceramic.

In an embodiment, the optical transceiver module may further include a light source disposed on the PCB, a second transmission line connected to the light source and disposed on the compensator, and a second high frequency connector connected to the second transmission line.

In an embodiment, the compensator may protrude from the PCB to compensate for a height difference from the light source.

In an embodiment, the optical transceiver module may further include a housing that shields the optical transceiver module from an outside space.

In an embodiment, the PCB may include a first metal layer connected to ground, a second metal layer connected to the first metal layer through a first via, a third metal layer connected to the second metal layer through a second via, and the plurality of dielectric layers disposed between the first metal layer and the second metal layer and between the second metal layer and the third metal layer.

In an embodiment, the plurality of metal layers may be formed of at least one of tungsten (W), molybdenum (Mb), copper (Cu), gold (Au), palladium (Pd) or silver (Ag).

In an embodiment, the optical transceiver module may further include a preamplifier that is disposed between the photodetector and the compensator to amplify the electrical signal.

In an embodiment, the power supply line may be connected to a circuit pattern on the PCB and the circuit pattern may be connected to the photodetector.

In an embodiment, the transmission line may include at least one of a single line, a differential line, or an array-type line.

In an embodiment, the transmission line may include at least one of a microstrip line, a suspended microstrip line, an inverted microstrip line, a single plan waveguide, a coplanar strip line, a slot line or a ground-type single plan waveguide, or a combination thereof.

In an embodiments of the inventive concept, an optical transceiver module includes a PCB configured to include a plurality of dielectric layers and a plurality of metal layers stacked alternately, a light source disposed on the PCB, a compensator disposed on one side on the PCB, a first transmission line provided on the compensator and extended to the light source, a power supply line configured to supply power to the light source, and a first high frequency connector configured to connect to the first transmission line to internally deliver the electrical signal, wherein the compensator protrudes from the PCB to compensate for a height difference from the light source.

In an embodiment, the optical transceiver module may further include a photodetector disposed on the PCB, a second transmission line connected to the photodetector and disposed on the compensator, and a second high frequency connector connected to the second transmission line.

In an embodiment, the compensator may protrude from the PCB to compensate for a height difference from the photodetector.

In an embodiment, the optical transceiver module may further include a laser driver that is disposed between the light source and the compensator to convert the electrical signal into a signal that the light source drives.

In an embodiment of the inventive concept, an optical transceiver module includes a PCB configured to include a plurality of dielectric layers and a plurality of metal layers stacked alternately, a light source disposed on the PCB, a photodetector disposed on the PCB to convert an optical signal into an electrical signal, a compensator disposed on one side on the PCB, a first transmission line provided on the compensator and extended to the light source, a second transmission line provided on the compensator and extended to the photodetector, a power supply line configured to supply power to the photodetector and the light source, a first high frequency connector configured to connect to the first transmission line to internally deliver the electrical signal, and a second high frequency connector configured to connect to the second transmission line to externally deliver the electrical signal, wherein the compensator protrudes from the PCB to compensate for height differences from the light source and the photodetector.

In an embodiment, the first transmission line of the compensator, the second transmission line, the light source, and the photodetector may have a same height.

In an embodiment, the optical transceiver module may further include a preamplifier disposed between the photodetector and the compensator to amplify the electrical signal, and a laser driver disposed between the light source and the compensator to convert the electrical signal into a signal that the light source drives.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a perspective view illustrating a photoreceiver module according to an embodiment of the present invention;

FIG. 2 is a perspective view illustrating the ceramic substrate of FIG. 1;

FIG. 3 is a sectional view taken along the line X-X′ of the ceramic substrate of FIG. 2;

FIG. 4 is a perspective view illustrating the first ceramic layer of the ceramic substrate shown in FIG. 2;

FIG. 5 is a perspective view illustrating first and second metallic layers of the ceramic substrate shown in FIG. 2;

FIG. 6 is a perspective view illustrating the second ceramic layer of the ceramic layer shown in FIG. 2;

FIG. 7 is a perspective view illustrating the uppermost layer of the ceramic substrate shown in FIG. 2;

FIG. 8 is a flowchart illustrating a method of manufacturing a photoreceiver module according to an embodiment of the present invention;

FIG. 9 is a perspective view illustrating a photoreceiver module according to another embodiment of the present invention;

FIG. 10 is a perspective view illustrating the ceramic substrate of FIG. 9;

FIG. 11 is a sectional view taken along the line Y-Y′ of the ceramic substrate of FIG. 10;

FIG. 12 is a perspective view illustrating a photoreceiver module according to another embodiment of the present invention;

FIG. 13 is a perspective view illustrating the ceramic substrate of FIG. 12;

FIG. 14 is a perspective view illustrating a photoreceiver module according to another embodiment of the present invention;

FIG. 15 is a perspective view illustrating the ceramic substrate of FIG. 14.

FIG. 16 is a diagram that represents an optical transceiver module according to an embodiment of the inventive concept;

FIG. 17 is a cross-sectional view of a printed circuit board (PCB) in FIG. 16;

FIG. 18 is a diagram that represents the PCB in FIG. 16;

FIG. 19 is a diagram that represents the housing of the optical transceiver module of FIG. 16;

FIG. 20 is a diagram that represents an optical transceiver module according to another embodiment of the inventive concept;

FIG. 21 is a diagram that represents an optical transceiver module according to still another embodiment of the inventive concept;

FIG. 22 is a diagram that represents an optical transceiver module according to still another embodiment of the inventive concept;

FIG. 23 is a diagram that represents an optical transceiver module according to still another embodiment of the inventive concept;

FIG. 24 is a diagram that represents an optical transceiver module according to still another embodiment of the inventive concept; and

FIG. 25 is a diagram that represents the housing of the optical transceiver module of FIG. 24.

### DETAILED DESCRIPTION OF PREFERRED EMBODIMENTS

It should be understood that the above general description and the following detailed description are all exemplary, and additional description of the claimed invention is provided. Reference numerals are shown in preferred embodiments of the present invention, and their examples are displayed in reference drawings. In any case, like reference numerals refer to like elements throughout.

Hereinafter, a photoreceiver module is used as an example of an electronic device to describe the features and functions of the present invention. However, those skilled in the art easily understand other advantages and performances based on the content listed herein. Moreover, the present invention may be implemented or applied through other embodiments. Furthermore, the detailed description may be modified or changed without departing from the scopes, technical ideas, and other purposes of the present invention.

Also, embodiments in the present disclosure are described with reference to ideal, exemplary cross sectional views and/or plan views of the inventive concept. The thicknesses of layers and regions in the drawings are exaggerated for the effective description of technical content. Thus, the forms of exemplary views may vary depending on manufacturing technologies and/or tolerances. Thus, embodiments of the inventive concept are not limited to shown specific forms and also include variations in form produced according to manufacturing processes. For example, an etch region shown in a rectangular shape may have a round shape or a shape having a certain curvature. Thus, regions illustrated in the drawings are exemplary, and the shapes of the regions illustrated in the drawings are intended to illustrate the specific shapes of the regions of devices and not to limit the scope of the inventive concept.

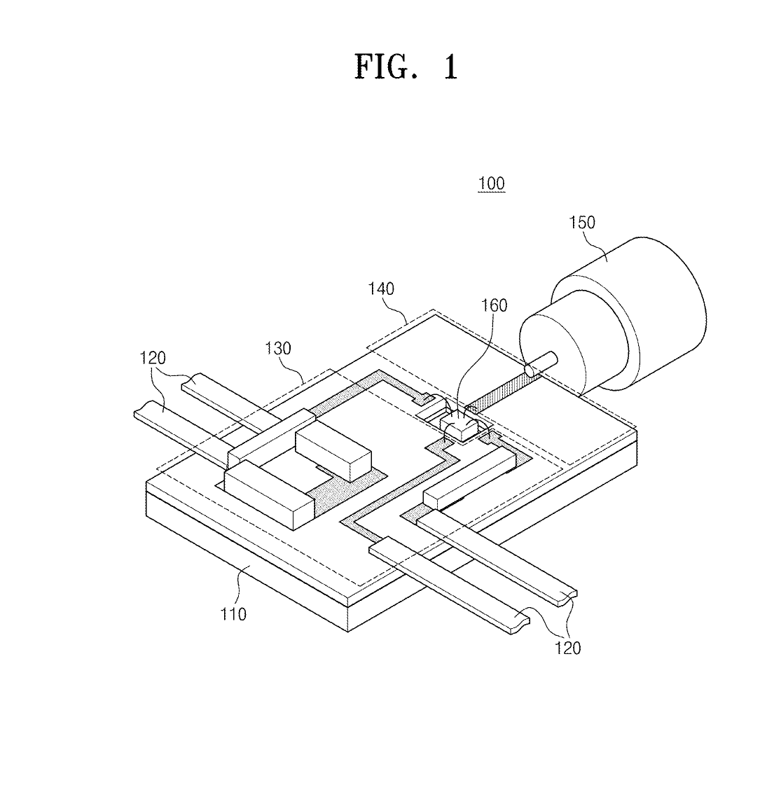

FIG. 1 is a perspective view illustrating a photoreceiver module according to an embodiment of the present invention. Referring to FIG. 1, the photoreceiver module 100 converts an optical signal received through an optical system (not shown) into a high frequency electrical signal and transmits the converted high frequency electrical signal to an external system through a high frequency connector 150.

A ceramic substrate 110 has a stacked layer structure of a metallic layer and a ceramic layer. Metallic layers are connected through a metallic via. A sub mount 140 is formed together when the ceramic substrate 110 is stacked. A circuit unit 130 and a photodetector 160 are mounted on the ceramic substrate 110. A stepped hole is manufactured in the ceramic substrate 110. The stepped hole is manufactured in consideration of the height of the photodetector 160. Due to the stepped hole, the positions of contact points of the circuit unit 130, the photodetector 160, and the sub mount 140 are close to each other. That is, due to the stepped hole, each height of the contact points becomes the same in a vertical direction from the bottom of the ceramic substrate 110.

A power supply line 120 is connected to the circuit unit 130. The power supply line 120 supplies necessary power to the photoreceiver module 100. The power supply line 120 supplies DC power to the circuit unit 130 and the photodetector 160.

The circuit unit 130 is configured by mounting circuit components on a circuit pattern stacked on the ceramic substrate 110. The circuit components include a resistor, an inductor, a capacitor, and an IC chip. The circuit unit 130 may include components of various functions. For example, the circuit unit 130 includes a noise reduction circuit. The noise reduction circuit reduces low frequency noise of DC power inputted through the power supply line 120. The reason is that the DC power inputted through the power supply line 120 still has many noise components. The circuit unit 130 may include additional circuits performing functions necessary for the photoreceiver module 100 such as a circuit controlling the photodetector 160.

The sub mount 140 delivers a high frequency signal converted by the photodetector 160 to the high frequency connector 150. The sub mount 140 is designed and manufactured to fit high-speed high frequency signal delivery. Therefore, when the specification of the photoreceiver module 100 is determined, the size and property of the sub mount 140 are determined. When the size of the sub mount 140 is determined, the ceramic substrate 110 is manufactured to fit the size. The sub mount 140 is manufactured together while the ceramic substrate 110 is stacked.

The high frequency connector 150 receives a high frequency signal through the sub mount 140. The high frequency connector 150 transmits the received high frequency signal to the outside. The specification of the high frequency connector 150 is predetermined in general.

The photodetector 160 converts an optical signal received through an optical system (not shown) into a high frequency electrical signal. The photodetector 160 is mounted on a stepped hole of the ceramic substrate 110. The stepped hole is manufactured in consideration of the height of the photodetector 160.

The circuit unit 130 is connected to the photodetector 160 through a bondwire. The photodetector 160 is connected to the sub mount 140 through a bondwire. As the usage length of a bondwire becomes longer, the high frequency property of the photoreceiver module 100 becomes worse. Due to the stepped hole, the positions of contact points of the circuit unit 130, the photodetector 160, and the sub mount 140 are close to each other. That is, due to the stepped hole, the height of each contact point is the same in a vertical direction from the bottom of the ceramic substrate 110. Therefore, the usage length of a bondwire becomes shorter. As a result, the high frequency property of the photoreceiver module 100 is improved.

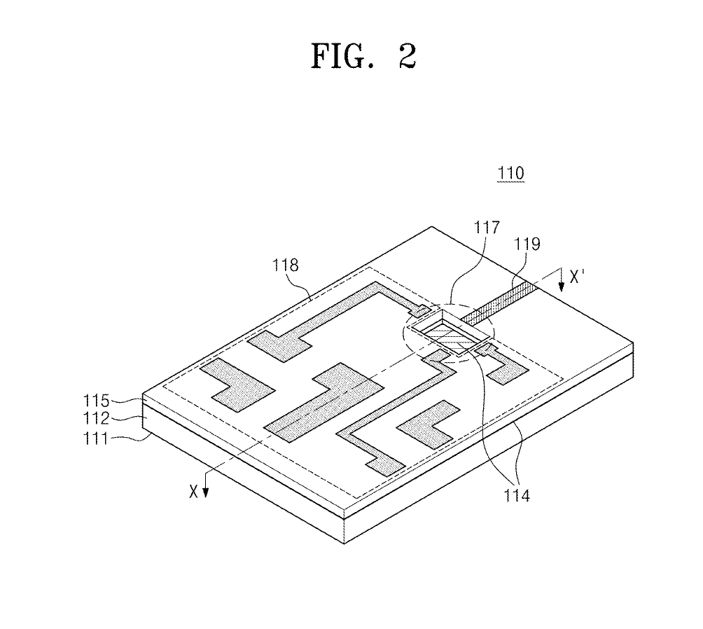

FIG. 2 is a perspective view illustrating the ceramic substrate of FIG. 1. Referring to FIG. 2, the ceramic substrate 110 is formed by stacking a metallic layer and a ceramic layer. The ceramic layer is formed by using a ceramic material used for manufacturing a stacked layer structure. The ceramic material may include alumina, aluminum nitride, and silicon carbide. The ceramic substrate 110 may include a low temperature co-fired ceramic substrate (LTCC) or a high temperature co-fired ceramic substrate (HTCC). It is apparent to those skilled in the art that there is no limit to a ceramic material and substrate type if they are used for manufacturing a stacked layer structure.

A first metallic layer 111 is a thin metallic layer. A material of the first metallic layer 111 is determined in consideration of thermal and electrical properties. For example, the material of the first metallic layer 111 may include W, Mb, Cu, or Ag. W or Mb is used for the HTCC. Cu or Ag is used for the LTCC. The first metallic layer 111 is connected to the ground.

A first ceramic layer 112 is a dielectric layer formed of ceramic material. The first ceramic layer 112 separates the first metallic layer 111 from a second metallic layer 114. The first ceramic layer 112 serves as a physical supporting part to fix individual components mounted on the ceramic substrate 110.

The second metallic layer 114 is a thin metallic layer. A material of the second metallic layer 114 is the same as the first metallic layer 111. The reason is to maintain the thermal and electrical properties of the ceramic substrate 110. Therefore, if the thermal and electrical properties are maintained constantly, the second metallic layer 114 may be stacked with a different material than the first metallic layer 111. The second metallic layer 114 is connected to the first metallic layer 111 through a metallic via penetrating the first ceramic layer 112. The metallic via is formed of the same material as the first and second metallic layers 111 and 114.

A second ceramic layer 115 is a dielectric layer formed of ceramic material. The second ceramic layer 115 is formed of the same material as the first ceramic layer 112. The reason is to uniformly maintain the thermal and electrical properties of the ceramic substrate 110. The thickness of the second ceramic layer 115 is determined according to the specification of the sub mount 140 of FIG. 1. For example, in order to maintain the impedance of a high frequency transmission line 119 to be about 50Ω, the second ceramic layer 115 is manufactured with a thickness of about 150 μm.

A stepped hole 117 is manufactured in a portion of the ceramic substrate 110 where the photodetector 160 is mounted. The stepped hole 117 is manufactured in consideration of the height of the photodetector 160. Due to the stepped hole 117, the positions of contact points of the circuit pattern 118, the photodetector 160, and the high frequency transmission line 119 are close to each other. That is, due to the stepped hole 117, the heights of the contact points are the same in a vertical direction from the bottom of the ceramic substrate 110. Therefore, the usage length of a bondwire becomes shorter.

The circuit pattern 118 is drawn according to a configuration of the circuit unit 130. The circuit pattern 118 is formed on the second ceramic layer 115. A portion connected to the ground of the circuit pattern 118 is connected to the second metallic layer 114 through a metallic via. The metallic via is formed of the same material as the second metallic layer 114. The circuit pattern 118 is formed of the same material as the second metallic layer 114.

The high frequency transmission line 119 is manufactured to be fit for transmitting a high frequency signal according to the specification of the sub mount 140. For example, the high frequency transmission line 119 is manufactured to deliver a high frequency signal at a speed of more than about 10 Gb/s. The high frequency transmission line 119 is manufactured to maintain its impedance to be about 50Ω. The high frequency transmission line 119 may be manufactured as one of a microstrip line, a coplanar waveguide, a grounded coplanar waveguide, or a combination thereof. The high frequency line 119 is formed at the position of the sub mount 140. The high frequency transmission line 119 is formed on the second ceramic layer 115.

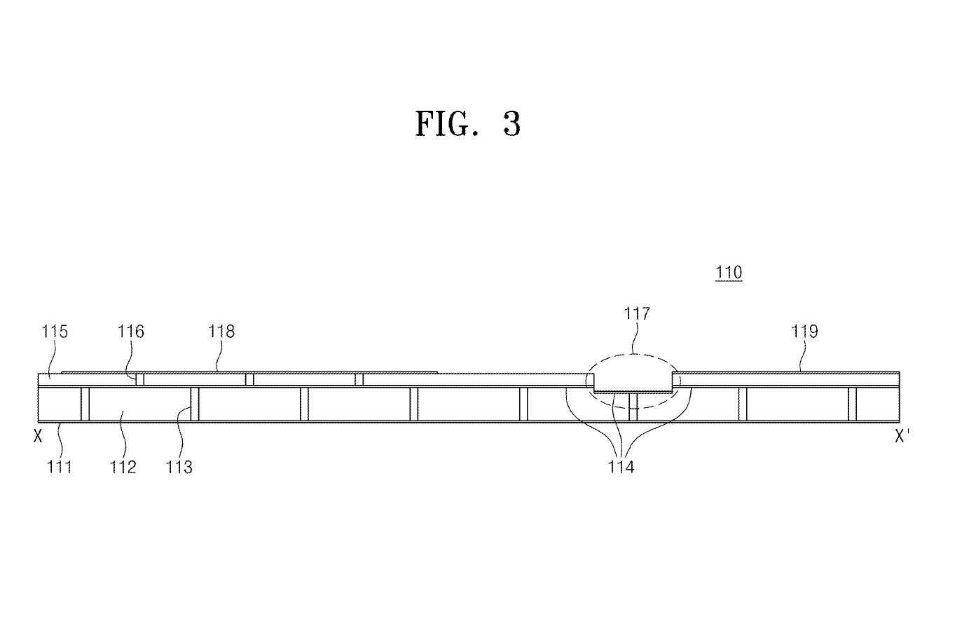

FIG. 3 is a sectional view taken along the line X-X′ of the ceramic substrate of FIG. 2. Referring to FIG. 3, the first ceramic layer 112 is formed between the first metallic layer 111 and the second metallic layer 114. The first metallic layer 111 and the second metallic layer 114 are connected to each other through the metallic via 113. The metallic via 113 penetrates the first ceramic layer 112 and are filled with the same material as the first and second metallic layers 111 and 114. The second ceramic layer 115 is formed on the second metallic layer 114. The circuit pattern 118 is formed at the position where the circuit unit 130 of FIG. 1 is mounted. The metallic via 116 is formed at a portion connected to the ground of the circuit pattern 118, as penetrating the second ceramic layer 115. The metallic via 116 is filled with the same material as the second metallic layer 114. The stepped hole 117 is manufactured at a position where the photodetector 160 is mounted. The stepped hole 117 is manufactured in consideration of the height of the photodetector 160. The high frequency transmission line 119 is formed at the position of the sub mount 140. The high frequency transmission line 119 is formed on the second ceramic layer 115.

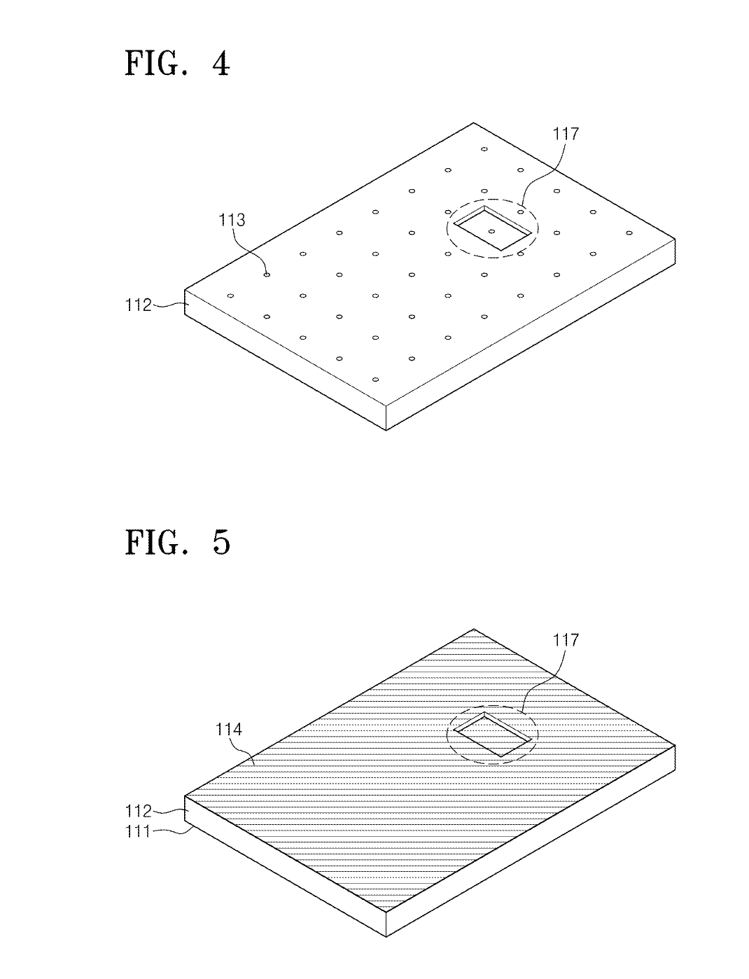

FIGS. 4 to 8 are views illustrating manufacturing processes of the ceramic substrate 110. FIG. 4 is a perspective view illustrating the first ceramic layer of the ceramic substrate shown in FIG. 2. Referring to FIG. 4, the first ceramic layer 112 is formed first. The first ceramic layer 112 is a dielectric layer formed of ceramic material. The first ceramic layer 112 is formed by stacking several ceramic layers where a hole of the metallic via 113 and a hole of the stepped hole 117 are formed. The first ceramic layer 112 is formed by heating the stacked several ceramic layers.

FIG. 5 is a perspective view illustrating first and second metallic layers of the ceramic substrate shown in FIG. 2. Referring to FIG. 5, the first metallic layer 111 is formed below the first ceramic layer 112. The second metallic layer 114 is formed on the first ceramic layer 112. The metallic via 113 penetrates the first ceramic layer 112 and is filled with the same material as the first and second metallic layers 111 and 114.

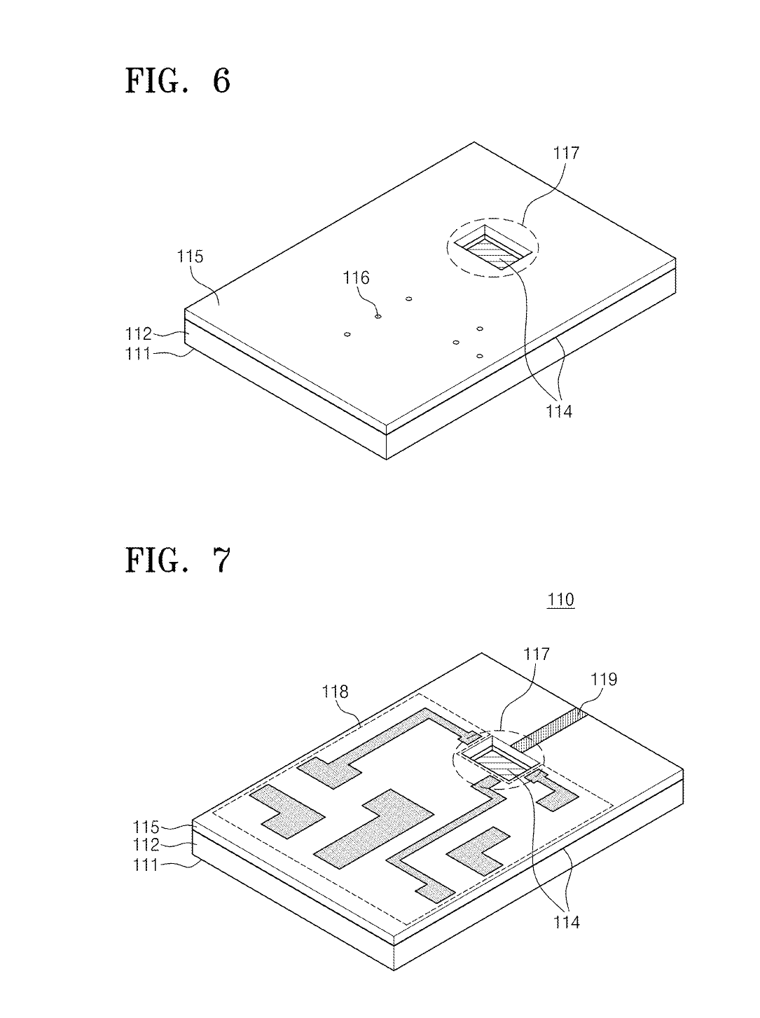

FIG. 6 is a perspective view illustrating the second ceramic layer of the ceramic layer shown in FIG. 2. Referring to FIG. 6, the second ceramic layer 115 may be formed on the second metallic layer 114 and may be formed of the same material as the first ceramic layer 112. The second ceramic layer 115 is formed by stacking several ceramic layers where a hole of the metallic via 116 and a hole of the stepped hole 117 are formed. The second ceramic layer 115 is formed by heating the stacked several ceramic layers. The metallic via 116 is formed by penetrating the second ceramic layer 115 at a portion connected to the ground of the circuit pattern 118. The metallic via 116 is filled with the same material as the second metallic layer 114. The stepped hole 117 is formed at a position where the photodetector 160 of FIG. 1 is mounted. The stepped hole 117 is formed in consideration of the height of the photodetector 160.

FIG. 7 is a perspective view illustrating the uppermost layer of the ceramic substrate shown in FIG. 2. The circuit pattern 118 is formed at a position where the circuit unit 130 of FIG. 1 is mounted. The circuit pattern 118 is formed on the second ceramic layer 115. The circuit pattern 118 is formed of the same material as the first and second metallic layers 111 and 114. The high frequency transmission line 119 is formed at the position of the sub mount 140. The high frequency transmission line 119 is formed on the second ceramic layer 115. Through these processes, the ceramic substrate 110 is completed.

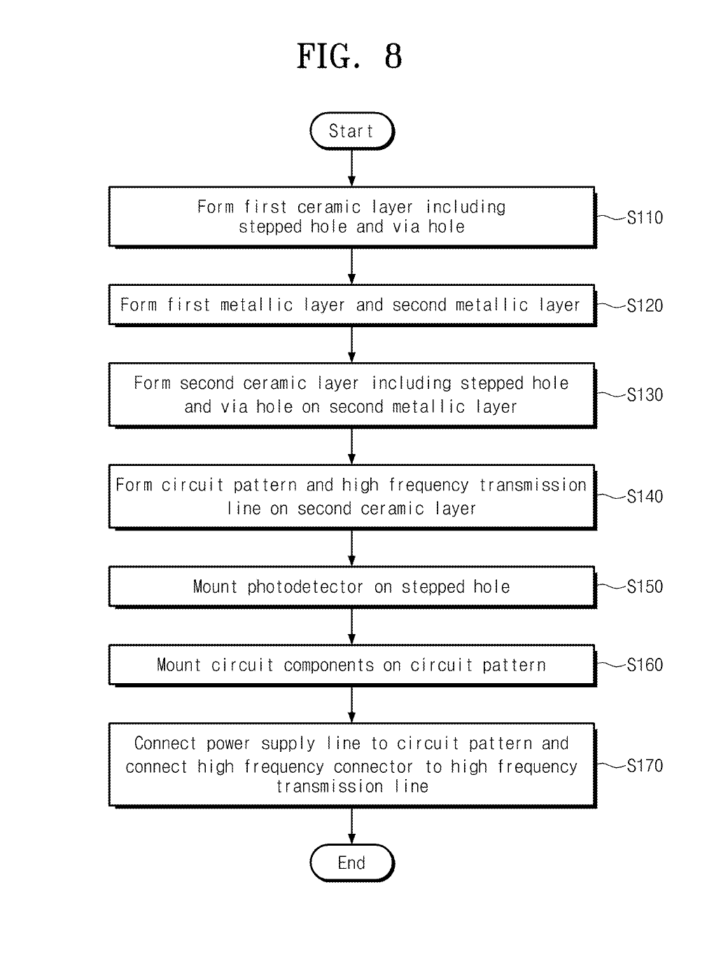

FIG. 8 is a flowchart illustrating a method of manufacturing a photoreceiver module according to an embodiment of the present invention. Hereinafter, this will be described with reference to FIGS. 1 to 7.

In operation S110, the first ceramic layer 112 is formed first. The first ceramic layer 112 is a dielectric layer formed of ceramic material. The first ceramic layer 112 is formed by stacking several ceramic layers where a hole of the metallic via 113 and a hole of the stepped hole 117 are formed. The first ceramic layer 112 is formed by heating the stacked several ceramic layers.

In operation S120, the first metallic layer 111 and the second metallic layer 114 are formed. The first metallic layer 111 is formed below the first ceramic layer 112. The second metallic layer 114 is formed on the first ceramic layer 112. The metallic via 113 is filled with the same material as the first and second metallic layers 111 and 114 are formed.

In operation S130, the second ceramic layer 115 is formed on the second metallic layer 114 and is formed of the same material as the first ceramic layer 112. The second ceramic layer 115 is formed by stacking several ceramic layers where a hole of the metallic via 116 and a hole of the stepped hole 117 are formed. The second ceramic layer 115 is formed by heating the stacked several ceramic layers. The metallic via 116 is formed by penetrating the second ceramic layer 115 at a portion connected to the ground of the circuit pattern 118. The metallic via 116 is filled with the same material as the second metallic layer 114. The stepped hole 117 is formed at a position where the photodetector 160 is mounted. The stepped hole 117 is formed in consideration of the height of the photodetector 160.

In operation S140, the circuit pattern 118 is formed at a position where the circuit unit 130 is mounted. The circuit pattern 118 is formed on the second ceramic layer 115. The circuit pattern 118 is formed of the same material as the first and second metallic layers 111 and 114. The high frequency transmission line 119 is formed at the position of the sub mount 140. The high frequency transmission line 119 is formed on the second ceramic layer 115.

In operation S150, the photodetector 160 is mounted at a portion of the stepped hole 117. The photodetector 160 is connected to the circuit pattern 118 and the high frequency transmission line 119 through a bondwire.

In operation S160, circuit components are mounted on the circuit pattern 118.

In operation S170, the power supply line 120 is connected to the high frequency connector 150. The power supply line 120 is connected to the circuit pattern 118. The high frequency connector 150 is connected to the high frequency transmission line 119.

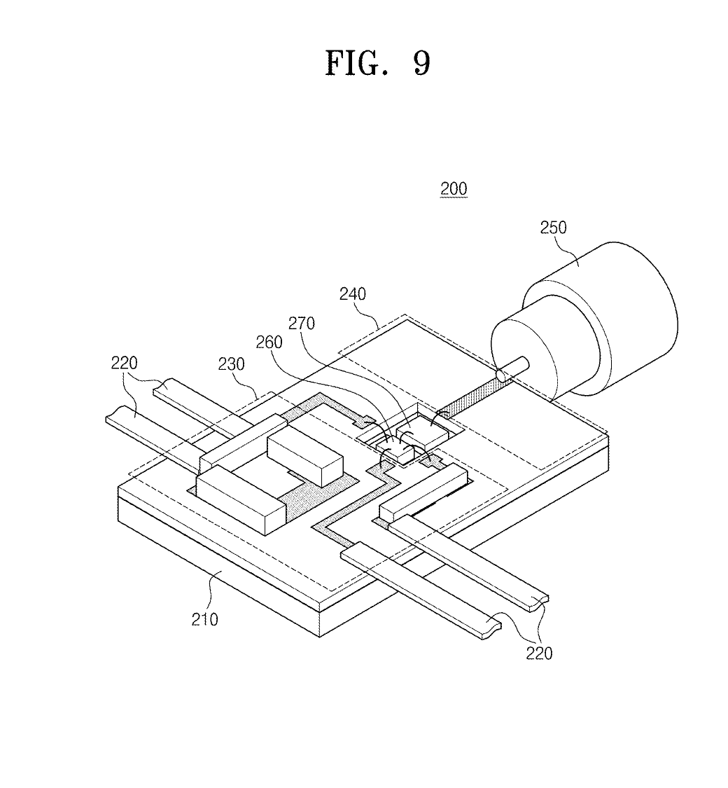

FIG. 9 is a perspective view illustrating a photoreceiver module according to another embodiment of the present invention. Referring to FIG. 9, a photoreceiver module 200 includes a photodetector 260 and a preamplifier 270. Therefore, a ceramic substrate 210 includes a stepped hole having two stages.

The ceramic substrate 210 includes a stacked layer structure of a metallic layer and a ceramic layer. Metallic layers are connected to each other through a metallic via. The ceramic substrate 210 serves as a supporting part of individual components. A power supply line 220 is connected to a circuit unit 230. The power supply line 220 supplies necessary power to the photoreceiver module 200. The circuit unit 230 is configured by mounting circuit components on a circuit pattern stacked on the ceramic substrate 210. The circuit unit 230 may include circuits of various functions. A sub mount 240 delivers a high frequency signal amplified by the preamplifier 270 to a high frequency connector 250. The sub mount 240 is formed together while the ceramic substrate 210 is stacked. The high frequency connector 250 receives a high frequency signal through the sub mount 240. The high frequency connector 250 transmits the received high frequency signal to the outside.

The photodetector 260 converts an optical signal received through an optical system (not shown) into a high frequency electrical signal. The photodetector 260 is mounted on the first stage of a stepped hole in the ceramic substrate 210. Therefore, the first stage of the stepped hole is manufactured in consideration of the height of the photodetector 260.

The preamplifier 270 amplifies a high frequency signal received from the photodetector 260. The amplifier high frequency signal is delivered to the sub mount 240. The preamplifier 270 is mounted on the second stage of the stepped hole in the ceramic substrate 210. Therefore, the second stage of the stepped hole is manufactured in consideration of the height of the preamplifier 270.

The circuit unit 230 and the photodetector 260, or the circuit unit 230 and the preamplifier 270 are connected to each other through a bondwire. The photodetector 260 and the preamplifier 270 are connected to each other through a bondwire. The preamplifier 270 and the sub mount 240 are connected to each other through a bondwire. As the usage length of a bondwire becomes longer, the high frequency property of the photoreceiver module 200 becomes worse. Due to the stepped hole, the positions of contact points of the circuit unit 230, the photodetector 260, the preamplifier 270, and the sub mount 240 are close to each other. That is, due to the stepped hole, the height of each contact point is the same in a vertical direction from the bottom of the ceramic substrate 210. Therefore, the usage length of a bondwire becomes shorter. As a result, the high frequency property of the photoreceiver module 200 is improved.

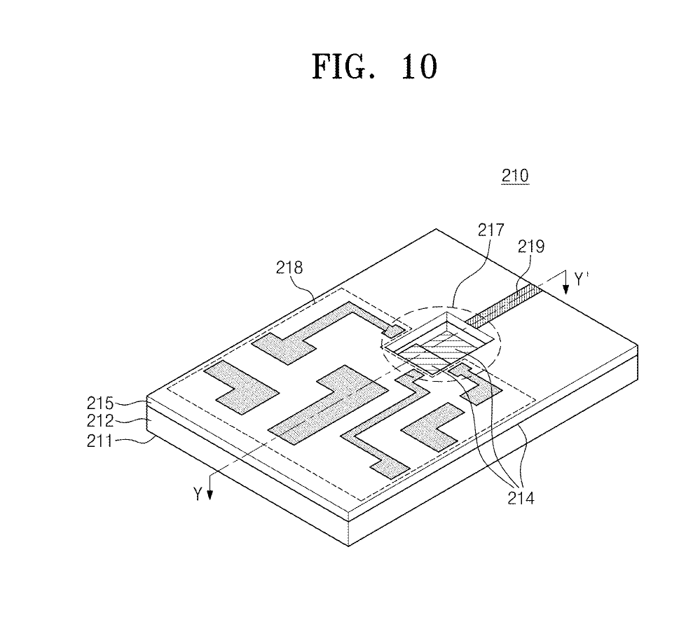

FIG. 10 is a perspective view illustrating the ceramic substrate of FIG. 9. Referring to FIG. 10, the ceramic substrate 210 is formed by stacking a metallic layer and a ceramic layer. The ceramic layer is formed by using a ceramic material used for manufacturing a stacked layer structure. A first metallic layer 211 is a thin metallic layer. The first metallic layer 211 is connected to the ground. A first ceramic layer 212 is a dielectric layer formed of ceramic material. The first ceramic layer 212 separates the first metallic layer 211 from a second metallic layer 214. The first ceramic layer 212 serves as a physical supporting part to fix components mounted on the ceramic substrate 210. The second metallic layer 214 is a thin metallic layer. The second metallic layer 214 is connected to the first metallic layer 211 through a metallic via penetrating the first ceramic layer 212. A second ceramic layer 215 is a dielectric layer formed of ceramic material. The thickness of the second ceramic layer 215 is determined according to the specification of the sub mount 240 of FIG. 10.

A stepped hole 217 is manufactured in a portion of the ceramic substrate 210 where the photodetector 260 and the preamplifier 270 are mounted. The stepped hole 217 has two stages. The first state of the stepped hole 217 is manufactured in consideration of the height of the photodetector 260. The second stage of the stepped hole 217 is manufactured in consideration of the height of the preamplifier 270. Due to the stepped hole 217, the positions of contact points of a circuit pattern 218, the photodetector 260, the preamplifier 270, and a high frequency transmission line 219 are close to each other. That is, due to the stepped hole 217, the heights of the contact points are the same in a vertical direction from the bottom of the ceramic substrate 210. Therefore, the high frequency property of the photoreceiver module 200 is improved.

The circuit pattern 218 is drawn according to a configuration of the circuit unit 230. The circuit pattern 218 is formed on the second ceramic layer 215. A portion connected to the ground of the circuit pattern 218 is connected to the second metallic layer 214 through a metallic via. The circuit pattern 218 is formed of the same material as the first and second metallic layers 211 and 214.

The high frequency transmission line 219 is manufactured to be fit for transmitting a high frequency signal according to the specification of the sub mount 240. The high frequency transmission line 219 is formed on the position of the sub mount 240. The high frequency transmission line 219 is formed on the second ceramic layer 215.

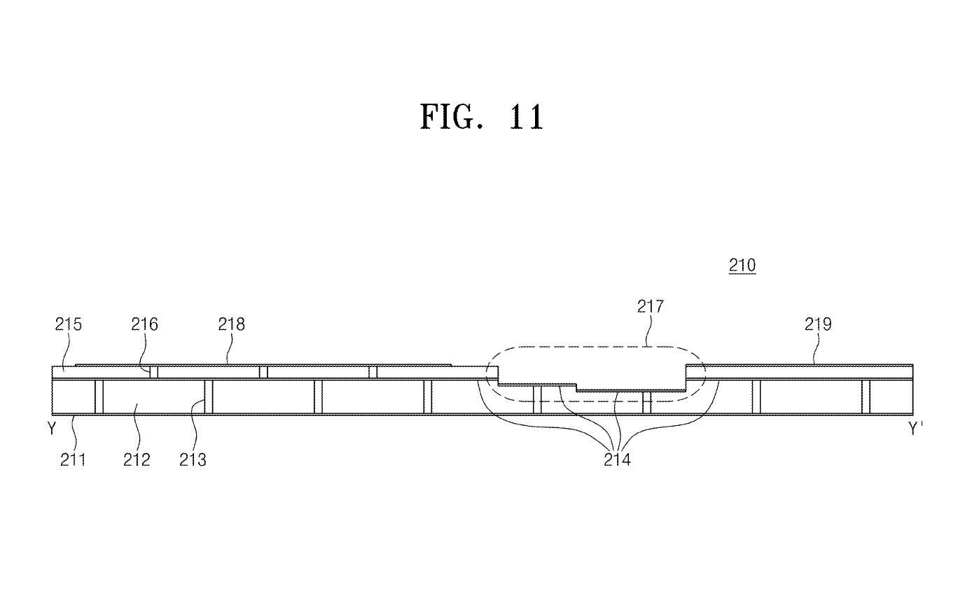

FIG. 11 is a sectional view taken along the line Y-Y′ of the ceramic substrate of FIG. 10. Referring to FIG. 11, the first ceramic layer 212 is formed between the first metallic layer 211 and the second metallic layer 214. The first metallic layer 211 and the second metallic layer 214 are connected to each other through the metallic via 213. The metallic via 213 penetrates the first ceramic layer 212 and are filled with the same material as the first and second metallic layers 211 and 214. The second ceramic layer 215 is formed on the second metallic layer 214. The circuit pattern 218 is formed at the position where the circuit unit 230 of FIG. 9 is mounted. The metallic via 216 is formed at a portion connected to the ground of the circuit pattern 218, as penetrating the second ceramic layer 215. The metallic via 216 is filled with the same material as the second metallic layer 214. The stepped hole 217 is manufactured at a position where the photodetector 260 and the preamplifier 270 are mounted. The stepped hole 217 has two stages. The first stage of the stepped hole 217 is manufactured in consideration of the height of the photodetector 260. The second stage of the stepped hole 217 is manufactured in consideration of the height of the preamplifier 270. The high frequency transmission line 219 is formed on the second ceramic layer 215 according to the position of the sub mount 240.

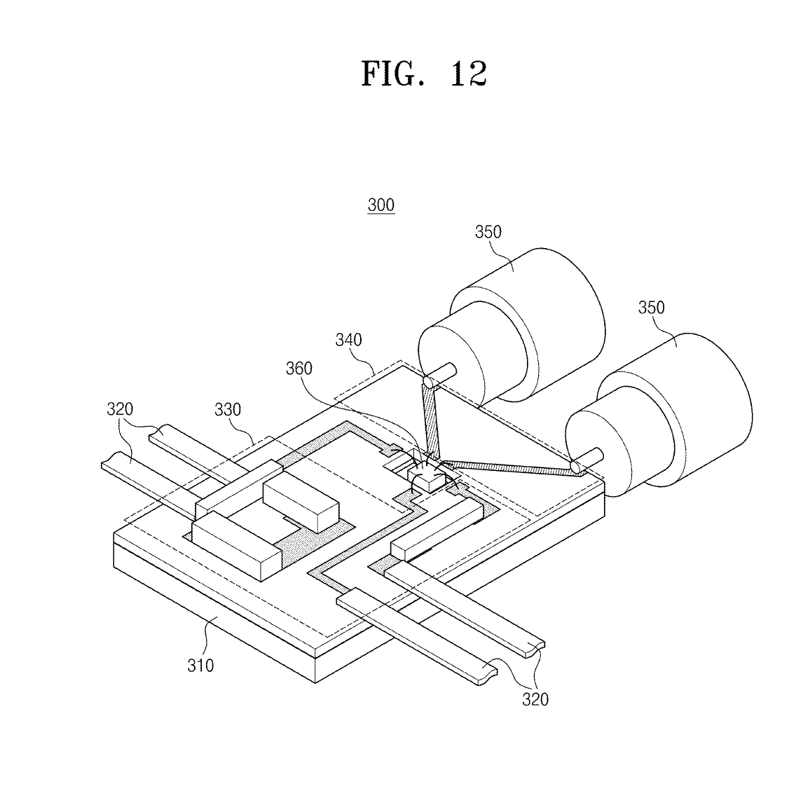

FIG. 12 is a perspective view illustrating a photoreceiver module according to another embodiment of the present invention. Referring to FIG. 12, the photoreceiver module 300 includes a photodetector 360 and a sub mount 340 of a differential transmission line.

A ceramic substrate 310 has a stacked layer structure of a metallic layer and a ceramic layer. Metallic layers are connected to each other through a metallic via. The ceramic substrate 310 serves as a supporting part of individual components. A power supply line 320 is connected to a circuit unit 330. The power supply line 320 supplies necessary power to the photoreceiver module 300. The circuit unit 330 is configured by mounting circuit components on a circuit pattern stacked on the ceramic substrate 310. The circuit unit 330 may include circuits of various functions.

The sub mount 340 delivers a high frequency signal converted by the photodetector 360 to a high frequency connector 350. The sub mount 340 has a differential transmission line. The sub mount 340 of the differential transmission line includes two high frequency transmission lines. The sub mount 340 is manufactured together while the ceramic substrate 310 is stacked. The high frequency connector 350 receives a high frequency signal through the sub mount 340. The high frequency connector 350 transmits the received high frequency signal to the outside.

The photodetector 360 converts an optical signal received through an optical system (not shown) into a high frequency electrical signal. The photodetector 360 is mounted on a stepped hole portion of the ceramic substrate 310. The stepped hole is manufactured in consideration of the height of the photodetector 360.

The circuit unit 330 and the photodetector 360 are connected to each other through a bondwire. The photodetector 360 and the sub mount 340 are connected to each other through a bondwire. As the usage length of a bondwire becomes longer, the high frequency property of the photoreceiver module 300 becomes worse. Due to the stepped hole, the positions of contact points of the circuit unit 330, the photodetector 360, and the sub mount 340 are close to each other. That is, due to the stepped hole, the height of each contact point is the same in a vertical direction from the bottom of the ceramic substrate 310. Therefore, the usage length of a bondwire becomes shorter. As a result, the high frequency property of the photoreceiver module 300 is improved.

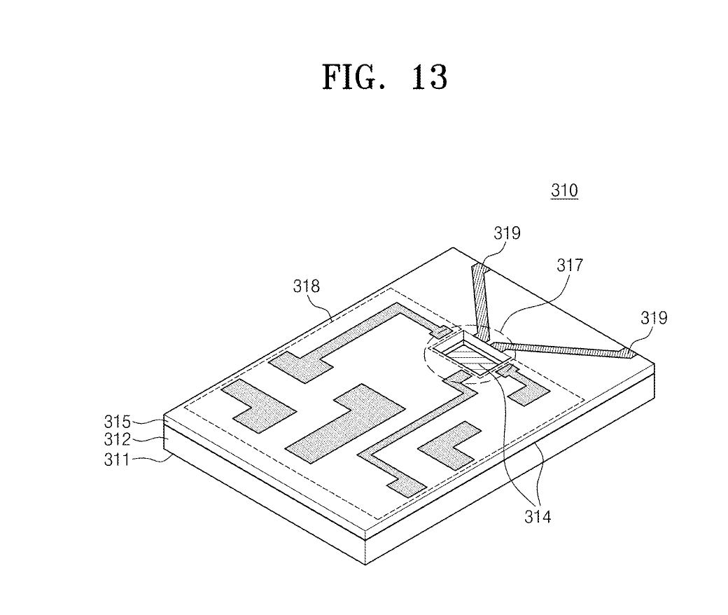

FIG. 13 is a perspective view illustrating the ceramic substrate of FIG. 12. Referring to FIG. 13, the ceramic substrate 310 is formed by stacking a metallic layer and a ceramic layer. The ceramic layer is formed by using a ceramic material used for manufacturing a stacked layer structure. The first metallic layer 311 is a thin metallic layer. The first metallic layer 311 is connected to the ground. A first ceramic layer 312 is a dielectric layer formed of ceramic material. The first ceramic layer 312 separates the first metallic layer 311 from a second metallic layer 314. The first ceramic layer 312 serves as a physical supporting part to fix components mounted on the ceramic substrate 310. The second metallic layer 314 is a thin metallic layer. The second metallic layer 314 is connected to the first metallic layer 311 through a metallic via penetrating the first ceramic layer 312. The metallic via is formed of the same material as the first and second metallic layers 311 and 314. A second ceramic layer 315 is a dielectric layer formed of ceramic material. The thickness of the second ceramic layer 315 is determined according to the specification of the sub mount 340 of FIG. 13. A stepped hole 317 is manufactured at a portion of the ceramic substrate 310 where the photodetector 360 is mounted. The stepped hole 317 is manufactured in consideration of the height of the photodetector 360. A circuit pattern 318 is drawn according to a configuration of the circuit unit 330. The circuit pattern 318 is stacked on the second ceramic layer 315. A portion connected to the ground in the circuit pattern 318 is connected to the second metallic layer 314 through a metallic via. The metallic via is formed of the same material as the second metallic layer 314.

The high frequency transmission line 319 is manufactured to be fit for transmitting a high frequency signal according to the specification of the sub mount 340. The sub mount 340 of a differential transmission line includes two high frequency transmission lines 319. The high frequency transmission line 319 is formed on the position of the sub mount 340. The high frequency transmission line 319 is formed on the second ceramic layer 315.

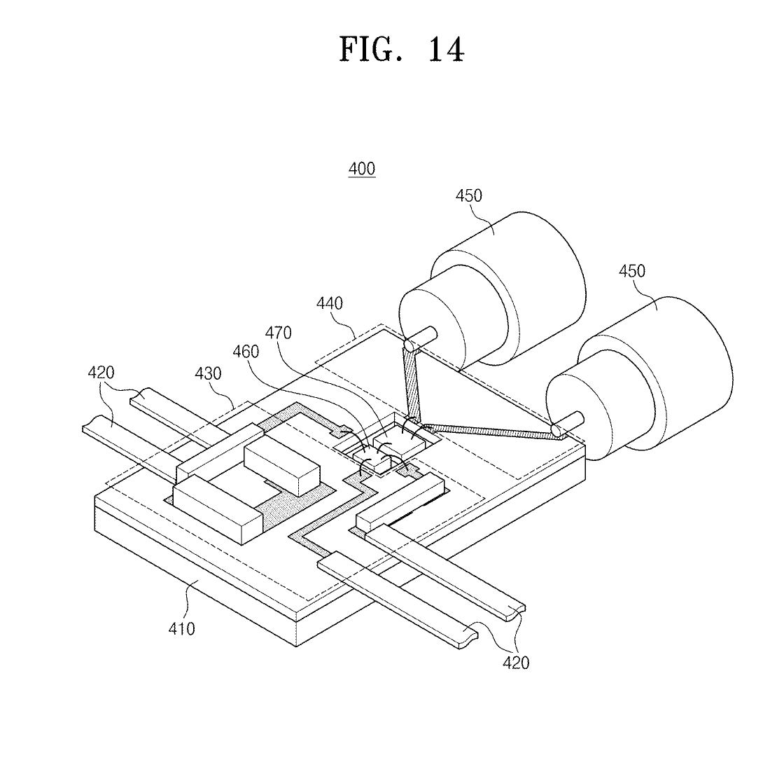

FIG. 14 is a perspective view illustrating a photoreceiver module according to another embodiment of the present invention. Referring to FIG. 14, the photoreceiver module 400 includes a photodetector 460, a preamplifier 470, and a sub mount 440 of a differential transmission line.

A ceramic substrate 410 has a stacked layer structure of a metallic layer and a ceramic layer. Metallic layers are connected to each other through a metallic via. The ceramic substrate 410 serves as a supporting part of individual components. A power supply line 420 is connected to a circuit unit 430. The power supply line 420 supplies necessary power to the photoreceiver module 400. The circuit unit 430 is configured by mounting circuit components on a circuit pattern stacked on the ceramic substrate 410. The circuit unit 430 may include circuits of various functions.

The sub mount 440 delivers a high frequency signal converted by the photodetector 460 to a high frequency connector 450. The sub mount 440 has a differential transmission line. The sub mount 440 of the differential transmission line includes two high frequency transmission lines. The sub mount 440 is manufactured together while the ceramic substrate 410 is stacked. The high frequency connector 450 receives a high frequency signal through the sub mount 440. The high frequency connector 450 transmits the received high frequency signal to the outside.

The photodetector 460 converts an optical signal received through an optical system (not shown) into a high frequency electrical signal. The photodetector 460 is mounted on the first state of a stepped hole in the ceramic substrate 410. Therefore, the first state of the stepped hole is manufactured in consideration of the height of the photodetector 460. The preamplifier 470 amplifies a high frequency signal received from the photodetector 440. The preamplifier 470 is mounted on the second state of a stepped hole in the ceramic substrate 410. Therefore, the second state of the stepped hole is manufactured in consideration of the height of the preamplifier 470.

The circuit unit 430 and the photodetector 460 or the preamplifier 470 are connected to each other through a bondwire. The photodetector 460 and the preamplifier 470 are connected to each other through a bondwire. The preamplifier 470 and the sub mount 440 are connected through a bondwire. As the usage length of a bondwire becomes longer, the high frequency property of the photoreceiver module 400 becomes worse. Due to the stepped hole, the positions of contact points of the circuit unit 430, the photodetector 460, the preamplifier 470, and the sub mount 440 are close to each other. That is, due to the stepped hole, the height of each contact point is the same in a vertical direction from the bottom of the ceramic substrate 410. Therefore, the usage length of a bondwire becomes shorter. As a result, the high frequency property of the photoreceiver module 400 is improved.

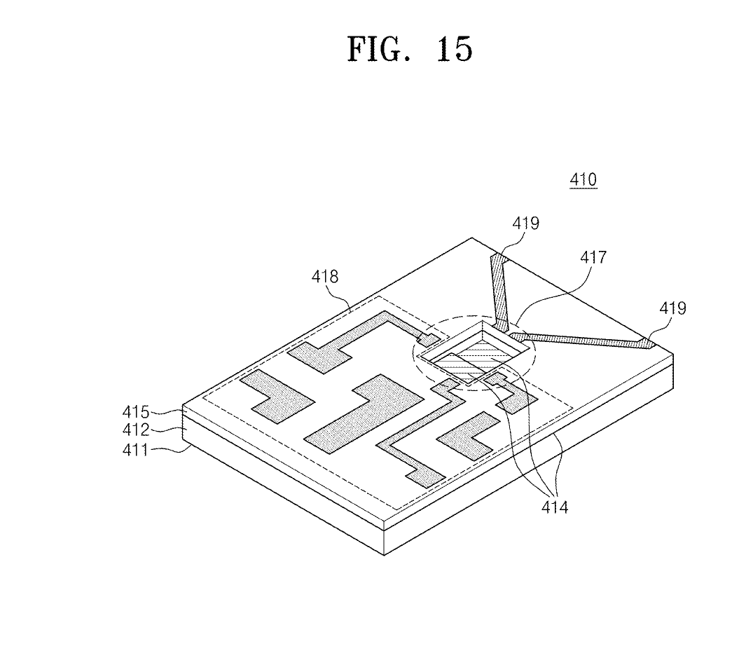

FIG. 15 is a perspective view illustrating the ceramic substrate of FIG. 14. Referring to FIG. 15, the ceramic substrate 410 is formed by stacking a metallic layer and a ceramic layer. The ceramic layer is formed by using a ceramic material used for manufacturing a stacked layer structure. A first metallic layer 411 is a thin metallic layer. The first metallic layer 411 is connected to the ground. A first ceramic layer 412 is a dielectric layer formed of ceramic material. The first ceramic layer 412 separates the first metallic layer 411 from a second metallic layer 414. The first ceramic layer 412 serves as a physical supporting part to fix components mounted on the ceramic substrate 410. The second metallic layer 414 is a thin metallic layer. The second metallic layer 414 is connected to the first metallic layer 411 through a metallic via penetrating the first ceramic layer 412. The metallic via is formed of the same material as the first and second metallic layers 411 and 414. A second ceramic layer 415 is a dielectric layer formed of ceramic material. The thickness of the second ceramic layer 415 is determined according to the specification of the sub mount 440 of FIG. 15.

A stepped hole 417 is manufactured at a portion of the ceramic substrate 410 where the photodetector 460 and the preamplifier 470 are mounted. The stepped hole 417 has two stages. The first stage of the stepped hole 417 is manufactured in consideration of the height of the photodetector 460. The second stage of the stepped hole 417 is manufactured in consideration of the height of the preamplifier 470. A circuit pattern 418 is drawn according to a configuration of the circuit unit 430. The circuit pattern 418 is stacked on the second ceramic layer 415. A portion connected to the ground in the circuit pattern 418 is connected to the second metallic layer 414 through a metallic via. The metallic via is formed of the same material as the second metallic layer 414. A high frequency transmission line 419 is manufactured to be fit for transmitting a high frequency signal according to the specification of the sub mount 440. The sub mount 440 of a differential transmission line includes two high frequency transmission lines 419. The high frequency transmission line 419 is stacked on the position of the sub mount 440. The high frequency transmission line 419 is formed on the second ceramic layer 415.

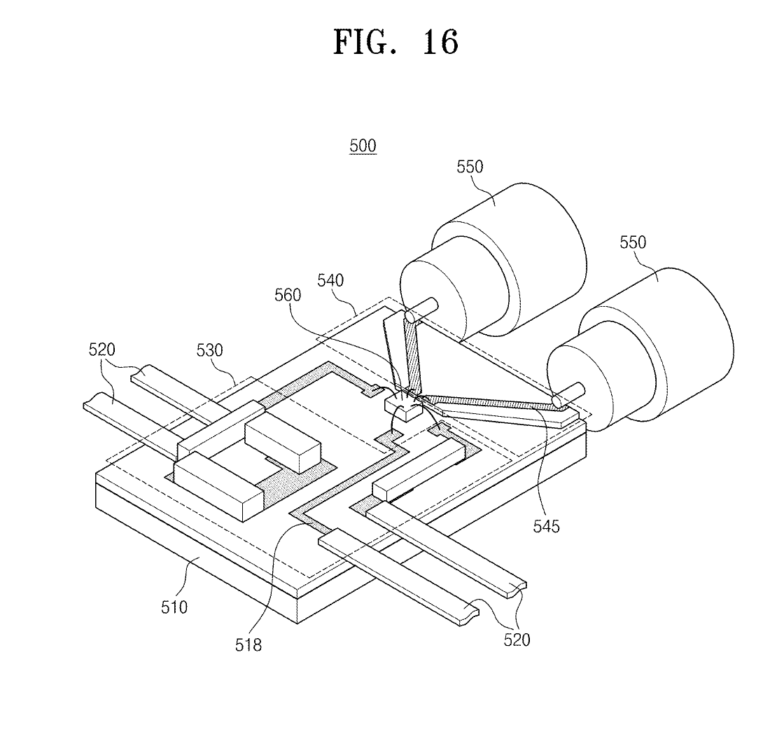

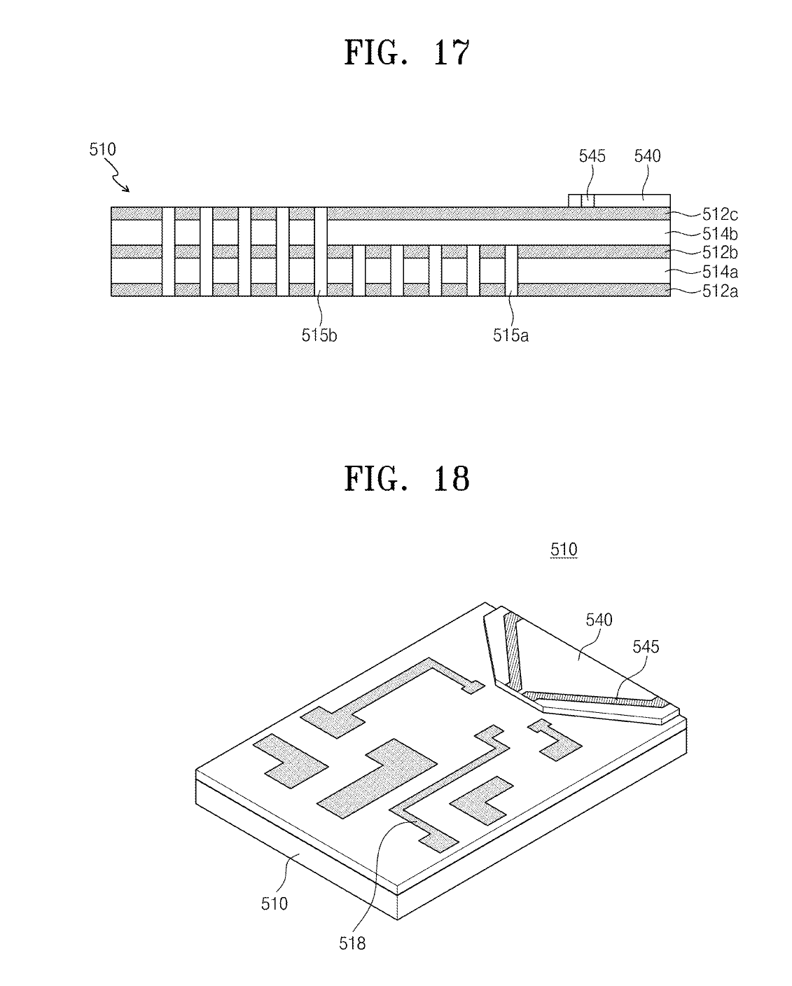

FIG. 16 is a diagram that represents an optical transceiver module according to an embodiment of the inventive concept, FIG. 17 is a cross-sectional view of a printed circuit board (PCB) in FIG. 16, and FIG. 18 is a diagram that represents the PCB in FIG. 16. Referring to FIGS. 16 to 18, the optical transceiver module 500 may include a PCB 510, a power supply line 520, a circuit unit 530, a compensator 540, a high frequency connector 550, and a photodetector 560. The optical transceiver module 500 converts an optical signal into an electrical signal to transmit the electrical signal to an external system through the high frequency connector 550.

The PCB 510 may include a plurality of metal layers 512a to 512c and a plurality of dielectric layers 514a and 514b. The metal layers 512a to 512c may include e.g., tungsten (W), molybdenum (Mb), copper (Cu), gold (Au), palladium (Pd), silver (Ag) or the like. The dielectric layers 514a and 514b may include e.g., alumina, aluminum nitride, silicon carbide, or the like. The dielectric layers 514a and 514b may perform a role in supporting the metal layers 512a to 512c, separating them from one another. The metal layers 512a to 512c may include a first metal layer 512a, a second metal layer 512b, and a third metal layer 512c, and the dielectric layers 514a and 514b may include a first dielectric layer 514a and a second dielectric layer 514b. The first metal layer 512a may be connected to the ground. The first metal layer 512a and the second metal layer 512b may be connected through a first via 515a, and the second metal layer 512b and the third metal layer 512c may be connected through a second via 515b. The first via 515a and the second via 515b may include e.g., tungsten (W), molybdenum (Mb), copper (Cu), gold (Au), palladium (Pd), silver (Ag) or the like. The first dielectric layer 514a may be disposed between the first metal layer 512a and the second metal layer 512b, and the second dielectric layer 514b may be disposed between the second metal layer 512b and the third metal layer 512c.

A circuit pattern 518 may be provided on the third metal layer 512c. The circuit pattern 518 may include e.g., tungsten (W), molybdenum (Mb), copper (Cu), gold (Au), palladium (Pd), silver (Ag) or the like. The circuit pattern 518 may be connected to the first metal layer 512a and the second metal layer 512b through the first via 515a and the second via 515b. Circuit components may be arranged on the circuit pattern 518 and it is possible to supply power to the circuit components through the circuit pattern 518.

The power supply line 520 may be connected to the circuit pattern 518 in the circuit unit 530. The power supply line 520 may supply power required for the optical transceiver module 500. The power supply line 520 may supply direct current (DC) power to the circuit unit 530 and the photodetector 560.

The circuit unit 530 may include the circuit components that are mounted on the circuit pattern 518 on the PCB 510. The circuit components may include a resistor, an inductor, a capacitor, an IC chip and the like. The circuit unit 530 may include circuits with various functions. For example, the circuit 530 may include a noise removal circuit. The noise removal circuit may remove the low-frequency noise of DC power that is input through the power supply line 520. The reason is that the DC power that is input through the power supply line 520 includes a lot of noise components. The circuit unit 530 may include additional circuits that perform functions required for the optical transceiver module 500, such as a circuit that controls the photodetector 560.

The compensator 540 may be provided on one side on the PCB 510. The compensator 540 may be provided on the PCB 510 to protrude therefrom. The compensator 540 may be connected to the circuit pattern 518 on the PCB 510. The compensator 540 may include any one of e.g., FR4, duroid, Taconic or ceramic.

The compensator 540 may include a transmission line 545 that delivers an electrical signal. One side of the transmission line 545 may be connected to the high frequency connector 550 and the other side of the transmission line 545 may be provided to face the photodetector 560. The transmission line 545 may be made up to be suitable for transmitting a high frequency signal according to the standard of the compensator 540. For example, the transmission line 545 may be manufactured to be capable of delivering the high frequency signal at a speed equal to or higher than 10 Gb/s. The transmission line 545 may be manufactured to be capable of maintaining impedance, about 50Ω. The transmission line 545 may be manufactured to be capable of maintaining impedance, about 100Ω in the case of a differential transmission line. The transmission line 545 may include at least one of a microstrip line, a suspended microstrip line, an inverted microstrip line, a single plan waveguide, a coplanar strip line, a slot line or a ground-type single plan waveguide, or a combination thereof. The transmission line 545 may include at least one of a single line, a differential line or an array-type line.

The compensator 540 may deliver the electrical signal converted by the photodetector 560 to the transmission line 545 without loss and deliver the electrical signal to the high frequency connector 550 through the transmission line 545. The height of the compensator 540 may be the same or similar to that of the photodetector 560 and other components. Accordingly, the compensator 540 may easily receive the electrical signal provide by the photodetector 560 to provide the received signal to the transmission line 545. It is possible to compensate the height difference between a plurality of components and the transmission line 545 through the compensator 540 without other manufacturing processes. When the standard of the optical transceiver module 500 is defined, the size and characteristic of the compensator 540 may also be determined. The compensator 540 may be made in the process of stacking the PCB 510, together.

The high frequency connector 550 may receive an electrical signal through the compensator 540. The high frequency connector 550 may be disposed on the same level as the transmission line 545 and they may be connected to each other. The high frequency connector 550 may be provided in plurality. The high frequency connector 550 transmits the received electrical signal to an external system. In the case that the transmission line 545 is of a differential type as in the embodiment, two high frequency connectors 550 may be connected.

The photodetector 560 may be provided on the PCB 510. The photodetector 560 may convert an optical signal received through an optical system into an electrical signal. For example, the photodetector 560 may be of a surface incidence type or waveguide type. The photodetector 560 may receive power by means of the circuit pattern 518.

The circuit unit 530 and the photodetector 560 may be connected by means of a bondwire. The photodetector 560 and the compensator 540 may be connected by means of a bondwire. The high frequency characteristic of the optical transceiver module 500 may be worsened with an increase in use length of the bondwire. When the PCB 510 with the compensator 540 is used, the circuit unit 530, the photodetector 560, and the transmission line 545 have the same height and the positions of their connection points are close to one another. Therefore, the use length of the bondwire shortens. Thus, the high frequency characteristic of the optical transceiver module 500 may be enhanced. Also, since the PCB 510 is used, production yield may be enhanced and it is easy to mount circuit components on the PCB 510, thus the manufacturing process of the optical transceiver module 500 may be simplified.

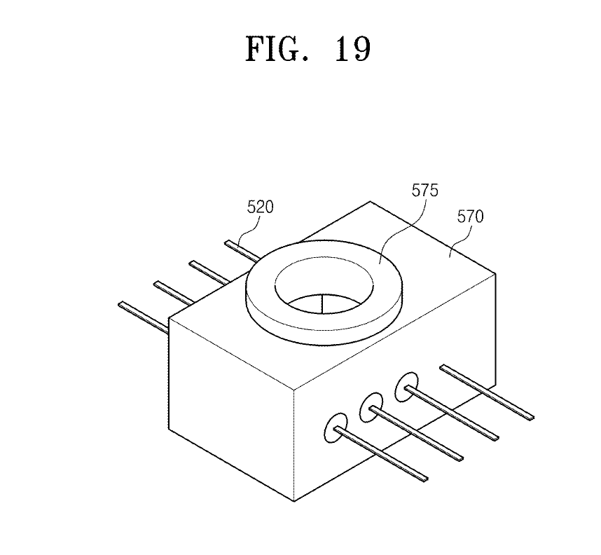

FIG. 19 is a diagram that represents the housing of the optical transceiver module. Referring to FIG. 19, a housing 570 may be provided which encloses the optical transceiver module 500 of FIG. 16. The housing 570 may physically support the optical transceiver module 500 of FIG. 16 and electromagnetically shield the optical transceiver module 500 from an outside space. The housing 570 may include an optical connector 575. The optical connector 575 may minimize the loss of an input optical signal and input the signal to the photodetector 560. The optical connector 575 may include an optical waveguide, lens, mirror, and the like.

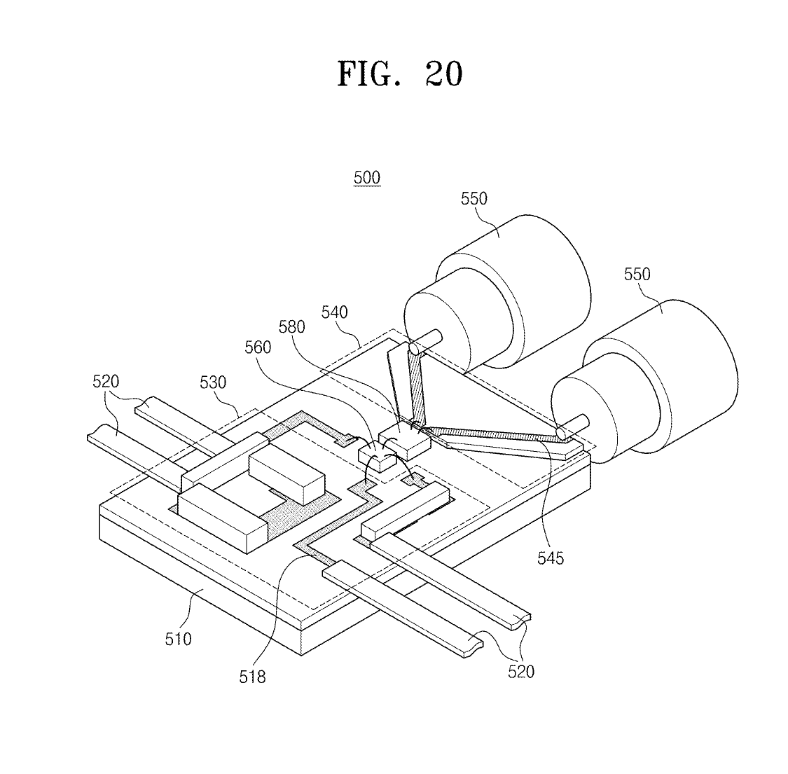

FIG. 20 is a diagram that represents an optical transceiver module according to another embodiment of the inventive concept. Differences from the embodiment that has been described with reference to FIGS. 16 to 18 are mostly described and similar components are omitted.

Referring to FIG. 20, the optical transceiver module 500 may further include a preamplifier 580. The preamplifier 580 may be provided on the PCB 510, and be disposed between the photodetector 560 and the compensator 540. The preamplifier 580 may amplify an electrical signal that is received from the photodetector 560. The amplified electrical signal is delivered to the compensator 540. The transmission line 545 may transmit the electrical signal amplified through the preamplifier 580 to the high frequency connector 550 without signal cancellation. The compensator 540, the photodetector 560, and the preamplifier 580 may have the same or similar heights. It is possible to compensator the height difference between the photodetector 560, the preamplifier 580 and the transmission line 545 through the compensator 540 without other manufacturing processes. The preamplifier 580 and the compensator 540 are connected by means of a bondwire. The high frequency characteristic of the optical transceiver module 500 may be worsen with an increase in use length of the bondwire. When the PCB 510 with the compensator 540 is used, the circuit unit 530, the photodetector 560, and the transmission line 545 have the same height and the positions of their connection points are close to one another. Therefore, the use length of the bondwire shortens. Thus, the high frequency characteristic of the optical transceiver module 500 may be enhanced.

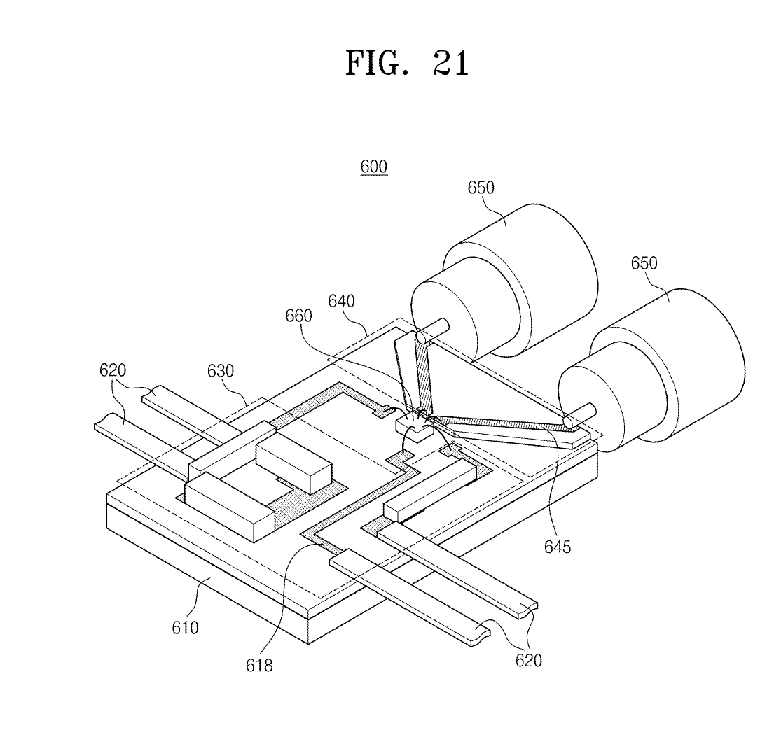

FIG. 21 is a diagram that represents an optical transceiver module according to still another embodiment of the inventive concept. Referring to FIG. 21, the optical transceiver module 600 may include a PCB 610, a power supply line 620, a circuit 630, a compensator 640, a high frequency connector 650, and a light source 660. The optical transceiver module 600 may convert an electrical signal delivered from the outside through the high frequency connector 650 and deliver the converted signal to the light source 660.

The PCB 610 in FIG. 21 may have the same or similar configuration to the PCB 510 in FIGS. 17 and 18. The PCB 610 may include a plurality of metal layers 612a to 612c and a plurality of dielectric layers 614a and 614b. The metal layers 612a to 612c may include e.g., tungsten (W), molybdenum (Mb), copper (Cu), gold (Au), palladium (Pd), silver (Ag) or the like. The dielectric layers 614a and 614b may include e.g., alumina, aluminum nitride, silicon carbide, or the like. The dielectric layers 614a and 614b may perform a role in supporting the metal layers 612a to 612c, separating them from one another. The metal layers 612a to 612c may include a first metal layer 612a, a second metal layer 612b, and a third metal layer 612c, and the dielectric layers 614a and 614b may include a first dielectric layer 614a and a second dielectric layer 614b. The first metal layer 612a may be connected to the ground. The first metal layer 612a and the second metal layer 612b may be connected through a first via 615a, and the second metal layer 612b and the third metal layer 612c may be connected through a second via 615b. The first via 615a and the second via 615b may include e.g., tungsten (W), molybdenum (Mb), copper (Cu), gold (Au), palladium (Pd), silver (Ag) or the like. The first dielectric layer 614a may be disposed between the first metal layer 612a and the second metal layer 612b, and the second dielectric layer 614b may be disposed between the second metal layer 612b and the third metal layer 612c.

A circuit pattern 618 may be provided on the third metal layer 612c. The circuit pattern 618 may include e.g., tungsten (W), molybdenum (Mb), copper (Cu), gold (Au), palladium (Pd), silver (Ag) or the like. The circuit pattern 618 may be connected to the first metal layer 612a and the second metal layer 612b through the first via 615a and the second via 615b. Circuit components may be arranged on the circuit pattern 618 and it is possible to supply power to the circuit components through the circuit pattern 618.

The power supply line 620 may be connected to the circuit pattern 618 in the circuit unit 630. The power supply line 620 may supply power required for the optical transceiver module 600. The power supply line 620 may supply DC power to the circuit unit 630 and the light source 660.

The circuit unit 630 may include the circuit components that are mounted on the circuit pattern 618 on the PCB 610. The circuit components may include a resistor, an inductor, a capacitor, an IC chip and the like. The circuit unit 630 may include circuits with various functions. For example, the circuit 630 may include a noise removal circuit. The noise removal circuit may remove the low-frequency noise of DC power that is input through the power supply line 620. The reason is that the DC power that is input through the power supply line 620 includes a lot of noise components. The circuit unit 630 may include additional circuits that perform functions required for the optical transceiver module 600, such as a circuit that controls the light source 660.

The compensator 640 may be provided on one side on the PCB 610. The compensator 640 may be provided on the PCB 610 to protrude therefrom. The compensator 640 may be connected to the circuit pattern 618 on the PCB 610. The compensator 640 may include any one of e.g., FR4, duroid, Taconic or ceramic.

The compensator 640 may include a transmission line 645 that delivers an electrical signal. One side of the transmission line 545 may be connected to the high frequency connector 650 and the other side of the transmission line 645 may be provided to face the light source 660. The transmission line 645 may be made up to be suitable for transmitting a high frequency signal according to the standard of the compensator 640. For example, the transmission line 645 may be manufactured to be capable of delivering the high frequency signal at a speed equal to or higher than 10 Gb/s. The transmission line 645 may be manufactured to be capable of maintaining impedance, about 50Ω. The transmission line 645 may be manufactured to be capable of maintaining impedance, about 100Ω in the case of a differential transmission line. The transmission line 645 may include at least one of a microstrip line, a suspended microstrip line, an inverted microstrip line, a single plan waveguide, a coplanar strip line, a slot line or a ground-type single plan waveguide, or a combination thereof. The transmission line 645 may include at least one of a single line, a differential line or an array-type line.

The compensator 640 may deliver the electrical signal received by the high frequency connector 650 to the transmission line 645 without loss and deliver the electrical signal to the light source 650 through the transmission line 645. The height of the compensator 640 may be the same or similar to that of the light source 660 and other components. Accordingly, the compensator 640 may easily provide the received electrical signal to the light source 660. It is possible to compensate the height difference between a plurality of components and the transmission line 645 through the compensator 640 without other manufacturing processes. When the standard of the optical transceiver module 600 is defined, the size and characteristic of the compensator 640 may also be determined. The compensator 640 may be made in the process of stacking the PCB 610, together.

The high frequency connector 650 may transmit an electrical signal received through an external system, to the compensator 540. The high frequency connector 650 may be disposed on the same level as the transmission line 645 and they may be connected to each other. The high frequency connector 650 may be connected to the light source 660 through the transmission line 645. In the case that the transmission line 645 is of a differential type as in the embodiment, two high frequency connectors 650 may be connected.

The light source 660 may be provided on the PCB 610. The light source 660 may be e.g., a surface-emitting laser or waveguide laser. The light source 660 may receive power by means of the circuit pattern 618.

The circuit unit 630 and the light source 660 may be connected by means of a bondwire. The light source 660 and the compensator 640 may be connected by means of a bondwire. The high frequency characteristic of the optical transceiver module 600 may be worsened with an increase in use length of the bondwire. When the PCB 610 with the compensator 640 is used, the circuit unit 630, the light source 660, and the transmission line 645 have the same height and the positions of their connection points are close to one another. Therefore, the use length of the bondwire shortens. Thus, the high frequency characteristic of the optical transceiver module 600 may be enhanced. Also, since the PCB 610 is used, production yield may be enhanced and it is easy to mount circuit components on the PCB 610, thus the manufacturing process of the optical transceiver module 600 may be simplified.

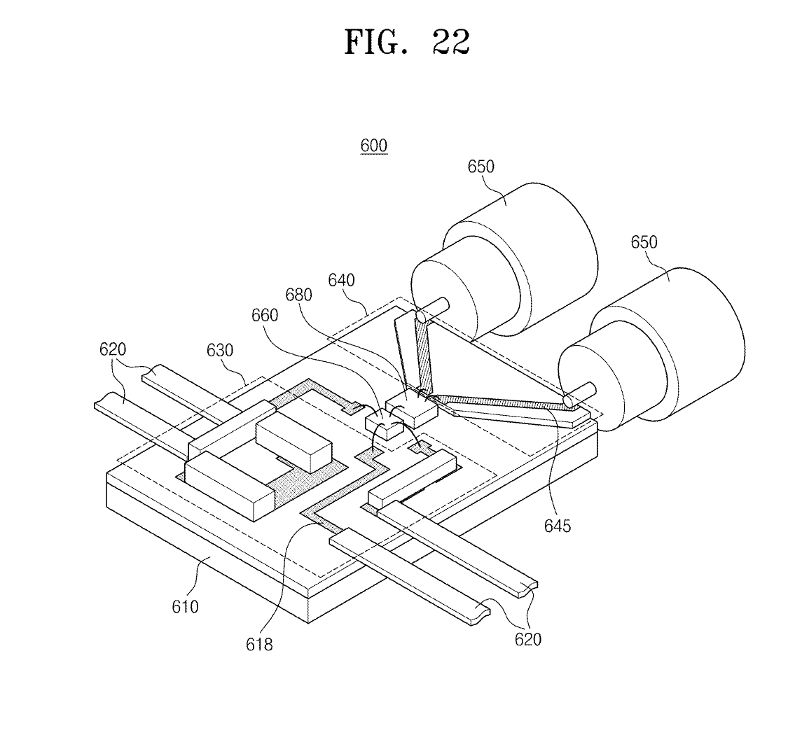

FIG. 22 is a diagram that represents an optical transceiver module according to still another embodiment of the inventive concept. Differences from the embodiment that has been described with reference to FIG. 21 are mostly described and similar components are omitted. Referring to FIG. 22, the optical transceiver module 600 may further include a laser driver 680. The laser driver 680 may be provided on the PCB 610, and be disposed between the light source 660 and the compensator 640. The laser driver 680 may convert the electrical signal received through the high frequency connector 650 into an electrical signal that is driven by the light source 660. The compensator 640, the light source 660 and the laser driver 680 may have the same or similar height. It is possible to compensator the height difference between the light source 660, the laser driver 680 and the transmission line 645 through the compensator 640 without other manufacturing processes. The laser driver 680 and the compensator 640 are connected by means of a bondwire. The high frequency characteristic of the optical transceiver module 600 may be worsened with an increase in use length of the bondwire. When the PCB 610 with the compensator 640 is used, the circuit unit 630, the light source 660, the laser driver 680, and the transmission line 645 have the same height and the positions of their connection points are close to one another. Therefore, the use length of the bondwire shortens. Thus, the high frequency characteristic of the optical transceiver module 600 may be enhanced.

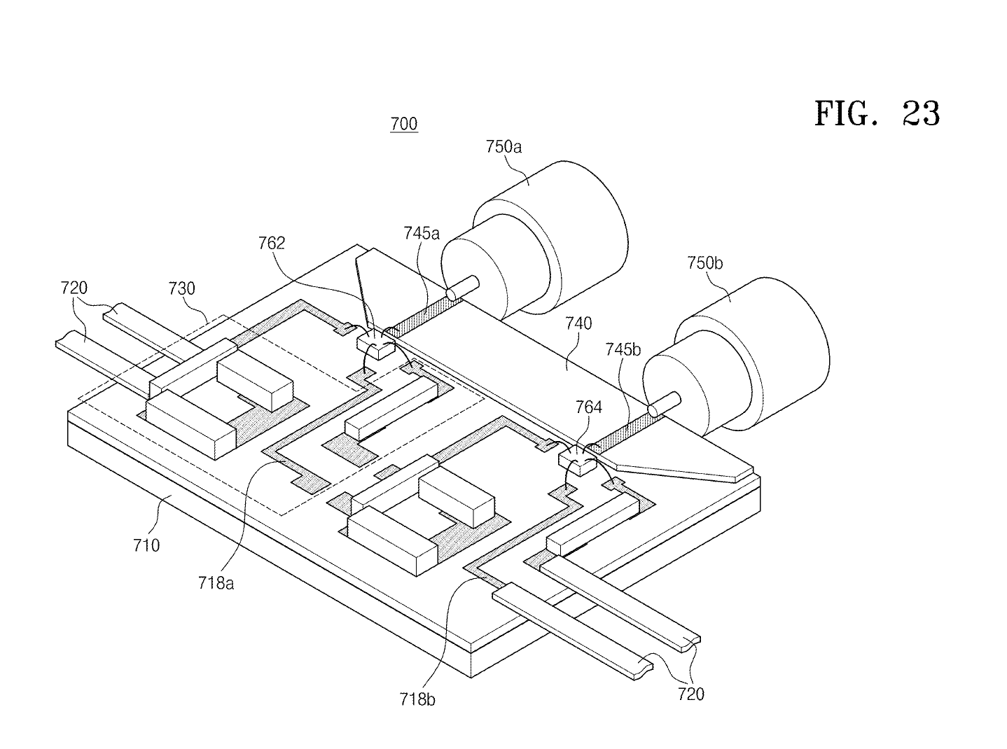

FIG. 23 is a diagram that represents an optical transceiver module according to still another embodiment of the inventive concept. For the simplicity of descriptions, the descriptions of like components are omitted. Referring to FIG. 23, an optical transceiver module 700 may include a PCB 710, a power supply line 720, a circuit unit 730, a compensator 740, a high frequency connector 750, a photodetector 762, and a light source 764. The optical transceiver module 700 may convert an optical signal into an electrical signal to transmit the electrical signal to an external system through the high frequency connector 750, and may convert an electrical signal delivered from the outside through the high frequency connector 750 to deliver the converted signal to the light source 760.

The compensator 740 may be disposed on one side on the PCB 710. A first transmission line 745a and a second transmission line 745b may be provided on the compensator 740. The compensator 740 may compensator the height difference between the photodetector 762, the light source 764, the first transmission line 745a, and the second transmission line 745b. Thus, the photodetector 762 may be disposed on the same level as the first transmission line 745a and the light source 764 may be disposed on the same level as the second transmission line 745b.

The first high frequency connector 750a may receive an electrical signal through the compensator 740. The photodetector 762 may convert an optical signal into an electrical signal, and the electrical signal may be delivered to the first high frequency connector 750a through the first transmission line 745a. The first high frequency connector 750a may transmit the received electrical signal to an external system. The second high frequency connector 750b may transmit an electrical signal received through an external system, to the compensator 740. The second transmission line 745b may deliver the received electrical signal to the light source 764.

The photodetector 762 and the light source 764 may be disposed on the PCB 710. The photodetector 762 may be disposed on a first circuit pattern 718a on the PCB 710 and the light source 764 may be disposed on a second circuit pattern 718b on the PCB 710. The first circuit pattern 718a and the second circuit pattern 718b may not overlap with each other. The reason is that the functions of the photodetector 762 and the light source 764 are different from each other. The photodetector 762 and the first high frequency connector 750a may be disposed to face each other, with the first transmission line 745a therebetween. The light source 764 and the second high frequency connector 750b may be disposed to face each other, with the second transmission line 745b therebetween.

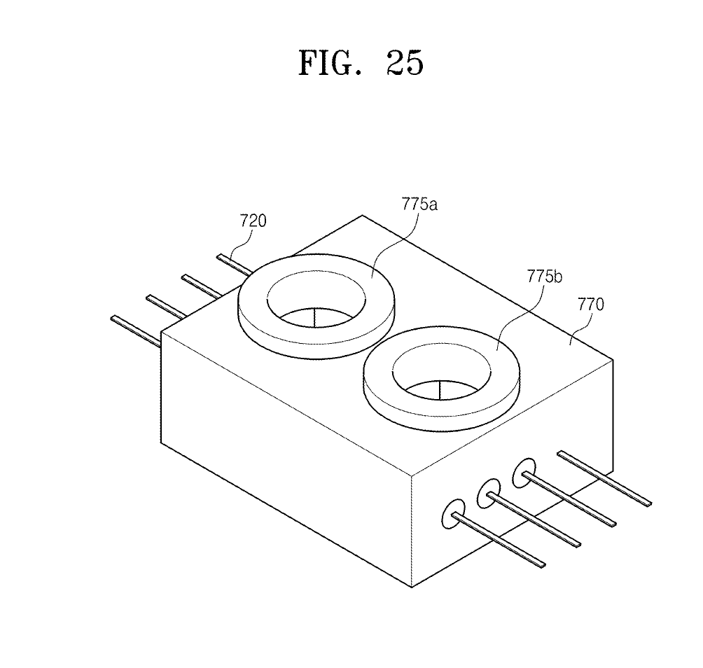

The optical transceiver module 700 may be disposed in a single housing 770 (of FIG. 25). It is possible to place the photodetector 762 and the light source 764 on a single PCB 710 to manufacture the optical transceiver module 700.

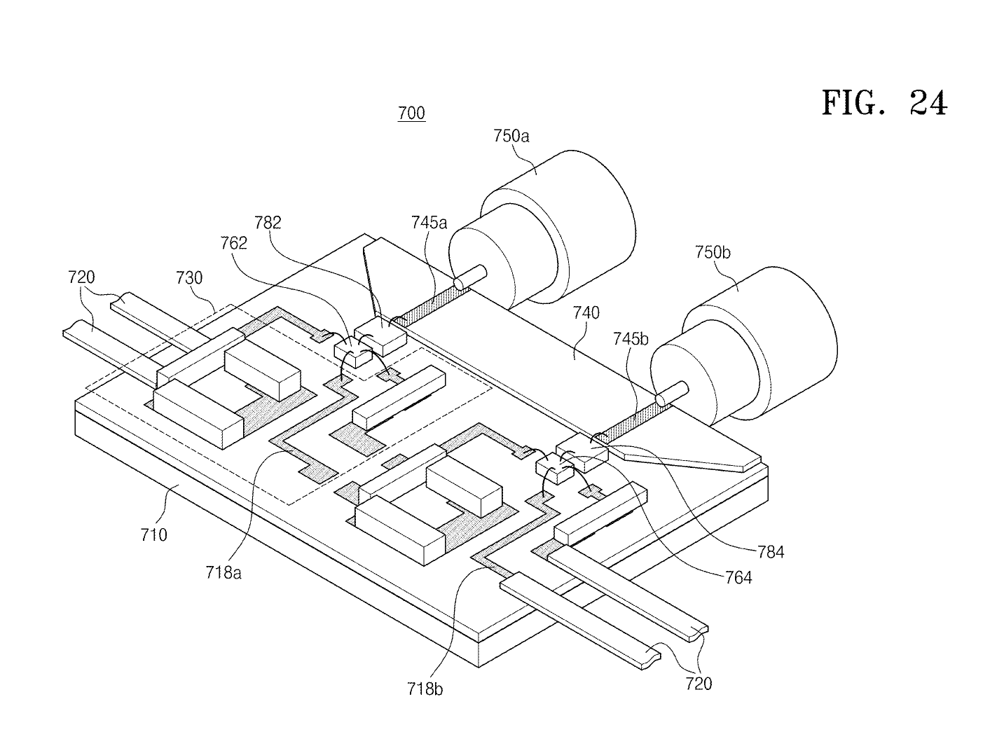

FIG. 24 is a diagram that represents an optical transceiver module according to still another embodiment of the inventive concept. For the simplicity of descriptions, the descriptions of like components are omitted. Referring to FIG. 24, the optical transceiver module 700 may further include a preamplifier 782 and a laser driver 784. The preamplifier 782 may be provided on the PCB 710, and be disposed between the photodetector 760 and the compensator 740. The photodetector 762, the preamplifier 782, the first transmission line 745a, and the first high frequency connector 750a may be disposed in a line. The photodetector 762, the preamplifier 782, and the first transmission line 745a may be placed on the same level through the compensator 740. The preamplifier 782 may amplify an electrical signal that is received from the photodetector 762.

The laser driver 784 may be provided on the PCB 710, and be disposed between the light source 760 and the compensator 740. The light source 764, the laser driver 784, the second transmission line 745b, and the second high frequency connector 750b may be disposed in a line. The light source 764, the laser driver 784, and the second transmission line 745b may be placed on the same level through the compensator 740. The laser driver 784 may convert the electrical signal received through the second high frequency connector 750b into an electrical signal that is driven by the light source 764.

The optical transceiver module 700 may be disposed in a single housing 770 (of FIG. 25). It is possible to place the photodetector 762, the light source 764, the preamplifier 782 and the laser driver 784 on a single PCB 710 to manufacture the optical transceiver module 700.

When the PCB 710 with the compensator 740 is used, the circuit unit 730, the photodetector 762, the light source 764, the preamplifier 782, the laser driver 784, the first transmission line 745a, and the second transmission line 745b have the same height and the positions of their connection points are close to one another. Therefore, the use length of the bondwire shortens. Thus, the high frequency characteristic of the optical transceiver module 700 may be enhanced. Also, since the PCB 710 is used, production yield may be enhanced and it is easy to mount circuit components on the PCB 710, thus the manufacturing process of the optical transceiver module 700 may be simplified.

Alternatively, the heights of the photodetector 762 and the light source 764 may be different from each other. Thus, the compensator 740 may be provided in plurality. The compensation unit 740 may also include a first compensator (not shown) for compensating for the height difference between the preamplifier 782 and the first transmission line 745a, and a second compensator (not shown) for compensating for the height difference between the light source 764, the laser driver 784, and the second transmission line 745b.

FIG. 25 is a diagram that represents the housing of the optical transceiver module of FIG. 24. Referring to FIG. 25, a housing 770 may be provided which encloses the optical transceiver module 700 of FIG. 24. The housing 770 may physically support the optical transceiver module 700 of FIG. 24 and electromagnetically shield the optical transceiver module 700 from an outside space. The housing 770 may include an optical connector 775. The optical connector 775 may include a reception connector 775a and a transmission connector 775b. The reception connector 775a may minimize the loss of an input optical signal and input the signal to the photodetector 760. The transmission connector 775b may minimize the loss of an optical signal output through the light source 760 and externally output the optical signal. The optical connector 775 may include an optical waveguide, lens, mirror, and the like.

According to an embodiment of the inventive concept, it is possible to provide an optical transceiver module that may compensate for the height between components through the compensator and decrease the length of the bondwire between circuit components to enhance transmission efficiency.

According to an embodiment of the inventive concept, it is possible to provide an optical transceiver module using a PCB to enhance production yield.

According to an embodiment of the inventive concept, it is possible to provide an optical transceiver module using a PCB to simplify manufacturing processes.

According to an embodiment of the inventive concept, it is possible to dispose an optical receiver module and an optical transmitter module in a single housing.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An optical transceiver module comprising:
a printed circuit board (PCB) configured to include a plurality of dielectric layers and a plurality of metal layers stacked alternately;
a photodetector disposed on the PCB to convert an optical signal into an electrical signal;
a compensator disposed on one side on the PCB and comprising a first transmission line that delivers an electrical signal;
a power supply line configured to supply power to the photodetector; and
a first high frequency connector configured to connect to the first transmission line to deliver the electrical signal,
wherein the PCB comprises a plurality of vias that electrically connect the plurality of dielectric layers and the plurality of metal layers, and
the compensator protrudes from the PCB to compensate for a height difference from the photodetector.

2. The optical transceiver module of claim 1, wherein the first transmission line of the compensator and the photodetector have a same height.

3. The optical transceiver module of claim 1, wherein the compensator comprises any one of FR4, duroid, taconic or ceramic.

4. The optical transceiver module of claim 1, further comprising:
a light source disposed on the PCB;
a second transmission line connected to the light source and disposed on the compensator; and
a second high frequency connector connected to the second transmission line.

5. The optical transceiver module of claim 4, wherein the compensator protrudes from the PCB to compensate for a height difference from the light source.

6. The optical transceiver module of claim 4, further comprising a housing that shields the optical transceiver module from an outside space.

7. The optical transceiver module of claim 1, wherein the PCB comprises:
a first metal layer connected to ground;
a second metal layer connected to the first metal layer through a first via;
a third metal layer connected to the second metal layer through a second via; and
the plurality of dielectric layers disposed between the first metal layer and the second metal layer and between the second metal layer and the third metal layer.

8. The optical transceiver module of claim 1, wherein the plurality of metal layers is formed of at least one of tungsten (W), molybdenum (Mb), copper (Cu), gold (Au), palladium (Pd) or silver (Ag).

9. The optical transceiver module of claim 1, further comprising a preamplifier that is disposed between the photodetector and the compensator to amplify the electrical signal.

10. The optical transceiver module of claim 1, wherein the power supply line is connected to a circuit pattern on the PCB and the circuit pattern is connected to the photodetector.

11. The optical transceiver module of claim 1, wherein the transmission line comprises at least one of a single line, a differential line, or an array-type line.

12. The optical transceiver module of claim 1, wherein the transmission line comprises at least one of a microstrip line, a suspended microstrip line, an inverted microstrip line, a single plan waveguide, a coplanar strip line, a slot line or a ground-type single plan waveguide, or a combination thereof.

13. An optical transceiver module comprising:
a PCB configured to include a plurality of dielectric layers and a plurality of metal layers stacked alternately;
a light source disposed on the PCB;
a compensator disposed on one side on the PCB;
a first transmission line provided on the compensator and extended to the light source;
a power supply line configured to supply power to the light source; and
a first high frequency connector configured to connect to the first transmission line to internally deliver the electrical signal,
the compensator protrudes from the PCB to compensate for a height difference from the light source.

14. The optical transceiver module of claim 13, further comprising:
a photodetector disposed on the PCB;
a second transmission line connected to the photodetector and disposed on the compensator; and
a second high frequency connector connected to the second transmission line.

15. The optical transceiver module of claim 14, wherein the compensator protrudes from the PCB to compensate for a height difference from the photodetector.

16. The optical transceiver module of claim 13, further comprising a laser driver that is disposed between the light source and the compensator to convert the electrical signal into a signal that the light source drives.

17. An optical transceiver module comprising:
a PCB configured to include a plurality of dielectric layers and a plurality of metal layers stacked alternately;
a light source disposed on the PCB;
a photodetector disposed on the PCB to convert an optical signal into an electrical signal;
a compensator disposed on one side on the PCB;
a first transmission line provided on the compensator and extended to the light source;
a second transmission line provided on the compensator and extended to the photodetector;
a power supply line configured to supply power to the photodetector and the light source;
a first high frequency connector configured to connect to the first transmission line to internally deliver the electrical signal; and
a second high frequency connector configured to connect to the second transmission line to externally deliver the electrical signal,
wherein the compensator protrudes from the PCB to compensate for height differences from the light source and the photodetector.

18. The optical transceiver module of claim 17, wherein the first transmission line of the compensator, the second transmission line, the light source, and the photodetector have a same height.

19. The optical transceiver module of claim 17, further comprising:
a preamplifier disposed between the photodetector and the compensator to amplify the electrical signal; and
a laser driver disposed between the light source and the compensator to convert the electrical signal into a signal that the light source drives.
